(19) United States
(12) Patent Application Publication
(10) Pub. No.: US 2009/0086449 A1
(43) Pub. Date: Apr. 2, 2009

(54) OPTICAL DEVICE AND MANUFACTURING METHOD THEREOF

(76) Inventors: Masanori MINAMIO, Osaka (JP); Masaki Taniguchi, Kyoto (JP); Hiroyuki Ishida, Kyoto (JP); Noriyuki Yoshikawa, Osaka (JP)

Correspondence Address: MCDERMOTT WILL & EMERY LLP, 600 13TH STREET, NW, WASHINGTON, DC, 20005-3096, US

(21) Appl. No.: 12/184,495

(22) Filed: Aug. 1, 2008

(30) Foreign Application Priority Data
Sep. 27, 2007 (JP) 2007-250714

(51) Int. Cl. H05K 7/00; B29D 11/00

(52) U.S. Cl. 361/760; 264/1.7

(57) ABSTRACT

An optical element mounted on a wiring board is sealed by a sealing resin except an optical function region. Wires connecting the wiring board with the optical element are also sealed by the sealing resin. The optical function region is exposed as a bottom surface of a recess whose side surface is formed by the sealing resin. The recess has a two-level structure of a bottom recess and a portion located over the bottom recess. A stepped portion extends from an upper end of a first side surface of the bottom recess to a lower end of a second side surface of the bottom recess.

### BACKGROUND OF THE INVENTION

1. Field of the Invention

The invention relates to an optical device and a manufacturing method thereof. More particularly, the invention relates to an optical device including an optical element and a wiring board having the optical element mounted thereon, in which an electrically connected portion of the optical element and the wiring board is resin-sealed, and a manufacturing method of the optical device.

2. Related Art

Optical devices having an optical semiconductor device, such as a solid state imaging element and an LED (Light Emitting Diode), mounted on a wiring board have been known in the art. An example of such an optical device has a hollow package structure in which a light-transmitting substrate is provided over an optical function surface in order to protect the optical function surface (for example, see Japanese Laid-Open Patent Publication No. 2003-332542). In another example of such an optical device, a transparent resin is applied to an optical function surface (for example, see Japanese Laid-Open Patent Publication No. 9-298249).

However, such optical devices cannot be used to receive or emit blue-violet laser light having a wavelength as short as 405 nanometers (nm) because transparent resin discolors with time and the transmittance changes. Such a change in transmittance does not occur when a glass plate with a special coating is used as a light-transmitting substrate. However, such a glass plate is very expensive, and the manufacturing cost is increased.

In view of the above problems, Japanese Laid-Open Patent Publication No. 2006-186288 proposes an optical function element module. In this optical function element module, a bank for damming up a liquid sealing resin is provided around an optical function element on a substrate on which the optical function element is mounted. The liquid sealing resin is dropped between the optical function element and the bank to fill the space between the optical function element and the bank with the liquid sealing resin. A package component member has a light-transmission hole corresponding to an optical function portion of the optical function element. The package component member is made in contact with the sealing resin by placing the package component member on the bank so that the light-transmission hole faces the optical function portion of the optical function element. The sealing resin is then cured to fix the package component member on the substrate, and the bank is cut off and removed at the end.

Japanese Laid-Open Patent Publication No. 2003-273371 proposes that a gas is blown to a surface of an optical function element during resin sealing in order to prevent accumulation of resin burrs on the surface, and that resin burrs are removed from the surface of the optical function element after resin sealing.

In manufacturing of the optical function element module described in Japanese Laid-Open Patent Publication No. 2006-186288, it is difficult to control dropping of the liquid sealing resin so as to form a desired amount of sealing resin with a desired shape only within a desired range. Moreover, the liquid sealing resin may be dropped onto the optical function portion when the liquid sealing resin is dropped between the optical function element and the bank. The liquid sealing resin may also flow onto the optical function portion when the package component member is placed on the bank. This results in reduction in yield. In order to reliably avoid such problems, the area of the optical function element needs to be increased to assure a sufficient distance between the end of the optical function element corresponding to the bank and the optical function portion. However, this makes it impossible to achieve size reduction which is one of the objects of Japanese Laid-Open Publication No. 2006-186288.

The invention is made in view of the above problems and it is an object of the invention to provide a small optical device having an exposed optical function region, which can be manufactured by a simple, low-cost method.

In order to solve the above problems, an optical device according to the invention includes an optical element, a wiring board, and a sealing resin, and an optical function region is exposed by a recess having a predetermined shape.

### SUMMARY OF THE INVENTION

An optical device according to the invention includes: an optical element having an optical function region on one surface; a wiring board having the optical element mounted thereon and electrically connected to the optical element; a sealing resin for sealing at least an electrically connected portion of the optical element and the wiring board; and a recess in which the optical function region serves as a bottom surface and at least a part of a side surface is formed by the sealing resin. The side surface has a first side surface extending from the bottom surface partway up a depth of the recess and a second side surface located above the first side surface. A bottom recess is formed by the bottom surface and the first side surface. A region surrounded by a lower end of the second side surface is larger in area than a region surrounded by an upper end of the first side surface. The first side surface and the second side surface are connected to each other by a stepped portion that extends from the upper end of the first side surface to the lower end of the second side surface. The optical function region herein refers to a light-receiving or light-emitting region, such as an imaging region of a solid-state imaging element (CMOS (Complementary Metal-Oxide Semiconductor) and CCD (Charge-Coupled Device)) and a light-emitting region of an LED, a surface-emitting laser, and the like. In the recess, the bottom surface is located on the lower side and the opening is located on the upper side.

In a preferred embodiment, the recess has a plurality of bottom recesses separated from each other by the sealing resin.

The second side surface may be formed by the sealing resin, and the first side surface may be formed by a resin different from the sealing resin. An example of the resin different from the sealing resin is a resist resin.

In a preferred embodiment, the recess has a plurality of bottom recesses separated from each other by the resin different from the sealing resin.

In a portion of the recess which is surrounded by the second side surface, the recess may have a tapered shape having a larger opening area on an upper side.

The bottom recess may have a tapered shape having a smaller opening area on a bottom-surface side.

The bottom recess may have a tapered shape having a larger opening area on a bottom-surface side.

According to the invention, a first method for manufacturing an optical device including an optical element having an optical function region on one surface, and a wiring board having the optical element mounted thereon and electrically connected to the optical element, includes the steps of: forming a resist on the optical function region of the optical element; mounting another surface of the optical element on the wiring board; electrically connecting the optical element with the wiring board; resin-sealing at least an electrically connected portion of the optical element and the wiring board by using a mold; and exposing the optical function region by removing the resist. The mold includes a lower mold placed on an opposite surface of an optical element mounting surface of the wiring board, and an upper mold for placing the wiring board having the optical element mounted thereon between the upper mold and the lower mold, and the upper mold has a projection that is in contact with the resist.

According to the invention, a second method for manufacturing an optical device including an optical element having an optical function region on one surface, and a wiring board having the optical element mounted thereon and electrically connected to the optical element, includes the steps of: forming a resist on the one surface of the optical element so as to surround the optical function region; mounting another surface of the optical element on the wiring board; electrically connecting the optical element with the wiring board; and resin-sealing at least an electrically connected portion of the optical element and the wiring board by using a mold. The mold includes a lower mold placed on an opposite surface of an optical element mounting surface of the wiring board, and an upper mold for placing the wiring board having the optical element mounted thereon between the upper mold and the lower mold. The upper mold has a projection that is in contact with the resist.

### BRIEF DESCRIPTION OF THE DRAWINGS

FIG. 1A is a cross-sectional view of an optical device according to a first embodiment of the invention, and FIG. 1B is a top view of the optical device of the first embodiment;

FIG. 2 is a flowchart of a manufacturing process of the optical device according to the first embodiment;

FIGS. 3A, 3B, 3C, and 3D are cross-sectional views illustrating the first half of the manufacturing process of the optical device according to the first embodiment;

FIGS. 4A, 4B, and 4C are cross-sectional views illustrating the last half of the manufacturing process of the optical device according to the first embodiment;

FIG. 5A is a cross-sectional view of an optical device according to a second embodiment of the invention, and FIG. 5B is a top view of the optical device of the second embodiment;

FIG. 6 is a cross-sectional view of an optical device according to a third embodiment;

FIG. 7 is a cross-sectional view of an optical device according to a fourth embodiment;

FIG. 8 is a cross-sectional view of an optical device according to a fifth embodiment; and

FIG. 9 is a flowchart of a manufacturing process of the optical device according to the fourth embodiment.

### DETAILED DESCRIPTION OF THE PREFERRED EMBODIMENTS

Hereinafter, embodiments of the invention will be described in detail with reference to the accompanying drawings. For simplicity of description, elements having substantially the same function are denoted with the same reference numerals and characters throughout the figures.

### First Embodiment

### Structure of an Optical Device

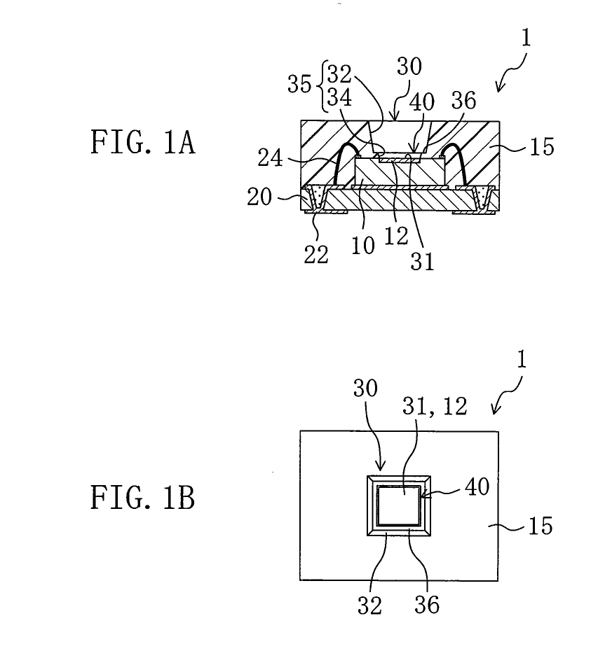

FIG. 1A is a cross-sectional view of an optical device (light-receiving device) 1 according to a first embodiment of the invention. FIG. 1B is a top view of the optical device 1. The optical device 1 is formed by resin-sealing an optical element (light-receiving element) 10 mounted on a wiring board 20 with a sealing resin 15 so as to expose an optical function region (light-receiving portion) 12.

The optical element 10 that is a semiconductor element has a rectangular flat plate shape. The optical function region 12 is formed in the center of one surface of the optical element 10. Electrode pads are provided on the periphery of this surface of the optical element 10. The optical element 10 is fixed to the wiring board 20 by mounting the other surface of the optical element 10 (the surface on which the optical function region 12 is not formed) on the wiring board 20. In other words, the optical element 10 is mounted on the wiring board 20 and the optical function region 12 faces upward.

The wiring board 20 has a plurality of through holes around the optical element mounting region. Through electrodes are formed by plating the through holes and embedding a conductive member in the through holes. On the side of the optical element mounting surface of the wiring board 20, the through electrodes are respectively electrically connected to connection wirings that are electrically connected by the electrode pads of the optical element 10 and wires 24. On the opposite surface of the optical element mounting surface, the through electrodes are respectively electrically connected to external connection electrodes 22 that are provided on the opposite surface. The external connection electrodes 22 are connected to external circuitry to receive power supply and to receive and output signals.

The sealing resin 15 seals the surface of the optical element 10 except the optical function region 12, the optical element mounting surface of the wiring board 20, and the wires 24 electrically connecting the optical element 10 with the wiring board 20. The optical function region 12 is exposed by a through hole provided in the sealing resin 15. In other words, the optical device 1 has a recess 30 having the optical function region 12 as a bottom surface 31. A side surface 35 of the recess 30 is formed by the sealing resin 15.

The side surface 35 of the recess 30 is divided into two parts in a depth direction of the recess 30: a lower first side surface 34 and an upper second side surface 32. A stepped portion 36 is provided between the lower first side surface 34 and the upper second side surface 32. A region surrounded by an upper end of the first side surface 34 has a larger area than a region surrounded by a lower end of the second side surface 32. Therefore, the stepped portion 36 faces upward. In other words, an upper end opening of the first side surface 34 has a larger area than a lower end opening of the second side surface 32. The first side surface 34 and the second side surface 32 are connected to each other by the stepped portion 36 extending outward from the upper end of the first side surface 34 to the lower end of the second side surface 32.

The first side surface 34 extends from the bottom surface 31 partway up the depth of the recess 30. The bottom surface 31 and the first side surface 34 form a bottom recess 40. The bottom recess 40 has a larger area at its upper end opening than at the bottom surface 31. The bottom recess 40 surrounded by the first side surface 34 has a tapered shape extending outward from the lower end to the upper end of the bottom recess 40.

A portion surrounded by the second side surface 32 also has a tapered shape extending outward from the lower end to the upper end of the portion.

As described above, the optical device 1 of this embodiment has the recess 30 having the optical function region 12 as the bottom surface 31. Therefore, the optical device 1 is preferable because it can directly receive short-wavelength light such as 405 nm and because the received light is not attenuated and reflected and light intensity does not change with time as opposed to an optical device having its upper part protected by a resin or a glass plate. Moreover, since the recess 30 is shaped as described above, disturbance light that is obliquely incident on the recess 30 is more likely to be reflected to the outside without entering the optical function region 12.

### Manufacturing Method of the Optical Device

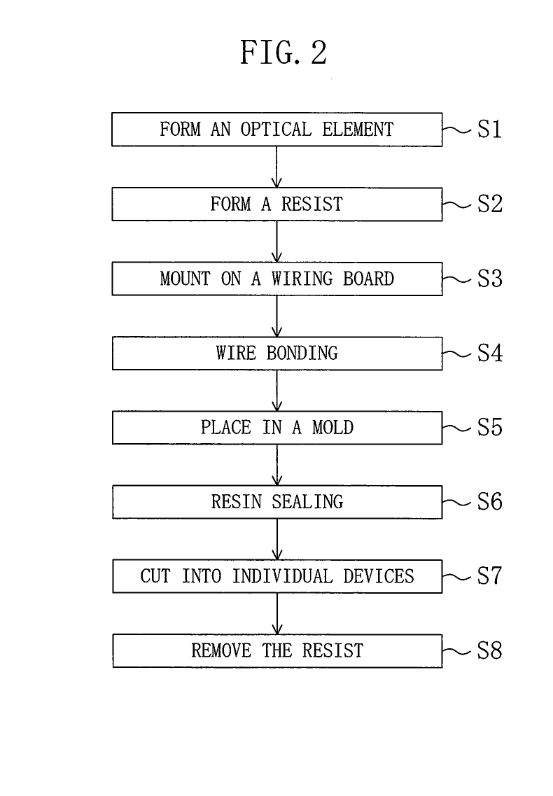

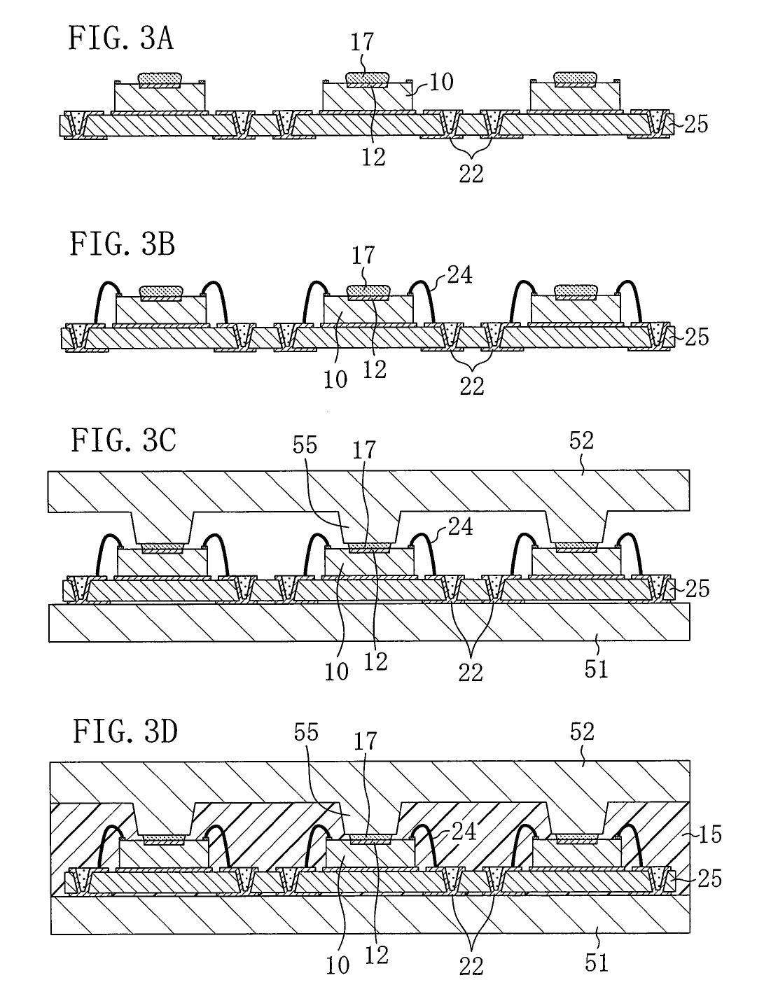

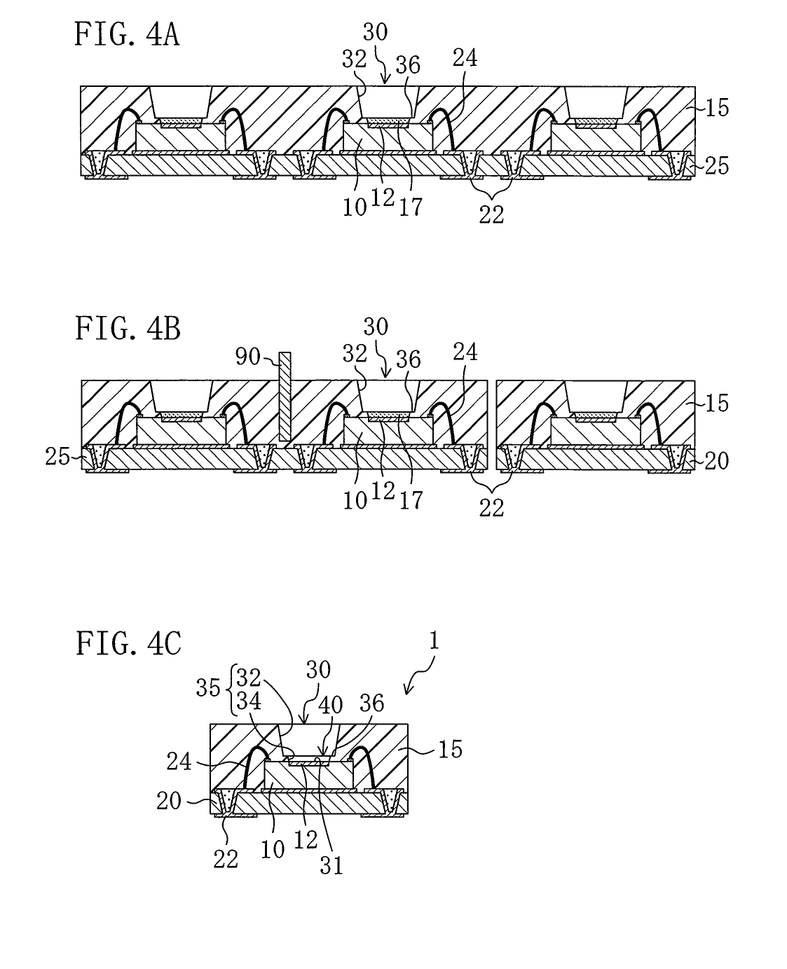

A method for manufacturing the optical device 1 according to this embodiment will now be described with reference to the flowchart of FIG. 2 and the cross-sectional views of FIGS. 3A through 3D and FIGS. 4A through 4C.

First, an optical element 10 is formed on a semiconductor substrate (S1). A resist 17 is formed on an optical function region 12 of the optical element 10 (S2). The resist 17 is herein formed only on the optical function region 12 by photolithography technology using positive photoresist.

As shown in FIG. 3A, the optical elements 10 having the resist 17 formed thereon are mounted on a continuous wiring board 25 (S3). The continuous wiring board 25 is a connection of a plurality of individual wiring boards 20. The continuous wiring board 25 is cut into the individual wiring boards 20 in a later step. Since the resist 17 is positive photoresist, the resist 17 extends wider in a horizontal direction at the top than at the bottom that is in contact with the optical function region 12. In other words, the resist 17 has a trapezoidal cross section in which the upper base is longer than the lower base.

As shown in FIG. 3B, electrode pads of the optical elements 10 are then respectively electrically connected to connection wirings on the continuous wiring board 25 by wire bonding (S4).

As shown in FIG. 3C, the continuous wiring board 25 having the optical elements 10 mounted thereon is then placed in a mold (S5). The mold is comprised of a lower mold 51 and an upper mold 52, and the continuous wiring board 25 is placed between the lower mold 51 and the upper mold 52. The surface of the continuous wiring board 25 on which no optical element is mounted is placed on a flat surface of the lower mold 51. The upper mold 52 has protrusions 55 protruding toward the respective optical elements 10.

The protrusions 55 are provided at such positions that the protrusions 55 are respectively in contact with the resists 17 when a sealing resin is introduced into the mold. The top end face of each protrusion 55 has a similar shape to that of the top surface of the resist 17 and is larger than the top surface of the resist 17. The projections 55 are placed in the mold so that the whole top surface of each resist 17 reliably abuts on the top end face of a corresponding one of the protrusions 55. Note that the resists 17 are somewhat flattened by pressing the upper mold 52. However, the resists 17 prevent the protrusions 55 from directly contacting the optical function regions 12. Therefore, the protrusions 55 do not damage the optical function regions 12.

The protrusions 55 have a tapered shape having a diameter reduced toward the top. This tapered shape prevents a part of the sealing resin 15 from adhering to the protrusions 55 and being removed when the mold is removed after resin sealing.

As shown in FIG. 3D, resin sealing is performed by introducing a resin into the mold (S6). By resin sealing, the surface of the optical elements 10 other than the optical function regions 12, the wires 24, and the optical element mounting surface of the continuous wiring board 25 are sealed by the sealing resin 15.

After the resin is solidified, the mold is removed, whereby the resin-sealed continuous wiring board 25 is obtained as shown in FIG. 4A.

The continuous wiring board 25 is then cut into individual devices by a blade 90 as shown in FIG. 4B (S7).

Finally, as shown in FIG. 4C, the resist 17 on the optical function region 12 is dissolved and removed by a solvent (S8). The optical device 1 is thus completed.

In this embodiment, the resist 17 is placed on the optical functional region 12. Therefore, the optical function region 12 can be exposed by removing the resist 17 without affecting the surrounding sealing resin 15, the wires 24, and the like. Formation and removal of the resist 17 are known, mature technologies in the semiconductor process, and therefore, can be accurately performed at low cost. The protrusion 55 has a tapered shape having a diameter reduced toward the top, and the top end face of the protrusion 55 has a larger area than that of the top surface of the resist 17. Therefore, the above-described shape of the second side surface 32 of the recess 30 and the stepped portion 36 can be easily formed. Manufacturing and device characteristics are not affected by reducing the distance between the optical function region 12 and the electrode pads. Therefore, a small optical device 1 can be implemented. Moreover, the shape of the bottom recess 40 can be easily formed by using a positive resist 17.

The top end face of each protrusion 55 of the upper mold 52 has a similar shape to that of the top surface of the resist 17, and has a larger area than that of the top surface of the resist 17. Therefore, even when there are a variation in size and position accuracy of the optical element 10 and the continuous wiring board 25 and a variation in mounting position of the optical element 10, the whole top surface of the resist 17 will abut within the range of the top end face of the projection 55 as long as these variations are within an allowable range as a product. Accordingly, it is assured that the sealing resin 15 that disturbs traveling of light is not present in the space located vertically above the optical function region 12.

In this embodiment, the optical device 1 having the exposed optical function region 12 is easily formed with high accuracy. In the semiconductor devices described in Japanese Laid-Open Patent Publication Nos. 9-298249 and 2003-332542, the optical function surface is exposed during the manufacturing process, as in the case of the optical device of this embodiment. In the semiconductor device described in Japanese Laid-Open Patent Publication Nos. 9-298249, however, a memory cell portion is exposed by making a window portion by melting a sealing resin with sulfuric acid or the like. Therefore, as the size of the semiconductor device is reduced, an electrode pad portion of a semiconductor element and Cu (copper) wirings are more likely to be corroded. It is therefore very difficult to apply this structure to an optical device for which size reduction has been required. Moreover, in the semiconductor device described in Japanese Laid-Open Patent Publication No. 2003-332542, resin sealing is performed with a mold after a silicone resin protective film is applied to a light-receiving surface. The protective film is peeled after resin sealing. Therefore, it is very difficult and time-consuming to apply the protective film at an accurate position and to peel the protective film at a time after resin sealing. Moreover, since a flat surface of an upper mold faces a solid imaging element, such a recess as in the optical device of this embodiment is not formed.

In an optical function module described in Japanese Laid-Open Patent Publication No. 2006-186288, it is very difficult to control the shape of a hole-side end face of a sealing resin that is present around a hole formed in a package component. Therefore, light may enter an optical function portion due to irregular reflection or the like at the hole-side end face of the sealing resin or at the lower edge of the hole in the package component. However, the optical device 1 of this embodiment does not have such a problem.

### Second Embodiment

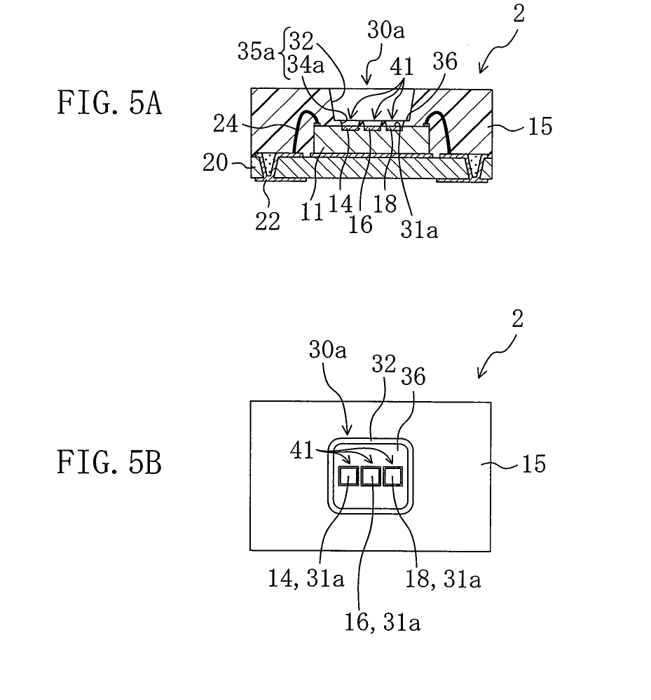

In an optical device 2 of a second embodiment shown in FIGS. 5A and 5B, an optical element 11 has three optical function regions 14, 16, and 18. The shape of a recess 30a is therefore partially different from that of the recess 30 of the first embodiment. However, components such as the wiring board 20 and the wires 24 are the same as those of the first embodiment. Therefore, only the differences from the first embodiment will be described below and description of the same portions will be omitted.

In the optical device 2 of this embodiment, three light-receiving portions (optical function regions 14, 16, and 18) having different functions are arranged next to each other. In this embodiment, the light-receiving portion located in the middle is a main light-receiving portion. The light-receiving portions located on both sides have a function to confirm if the main light-receiving portion is properly receiving light or not. In other words, if a predetermined amount of light is not incident on the light-receiving portions located on both sides, an electric signal (information) is transmitted to a controller LSI of a light-receiving device module in order to perform correction of the position and adjustment of the received light amount.

The recess 30a is the same as the recess 30 of the first embodiment in the second side surface 32 of a side surface 35a. However, a first side surface 34a of the side surface 35a is a side surface of each of three bottom recesses 41, 41, and 41 having the optical function regions 14, 16, and 18 as their respective bottom surfaces 31a. As in the first embodiment, the bottom recesses 41, 41, and 41 have a tapered shape having a smaller opening area at the bottom.

A method for manufacturing the optical device 2 of this embodiment is the same as that of the first embodiment except that the resist 17 is placed on each of the three optical function regions 14, 16, and 18.

The optical device 2 of this embodiment and the manufacturing method thereof have the same effects as those of the first embodiment.

### Third Embodiment

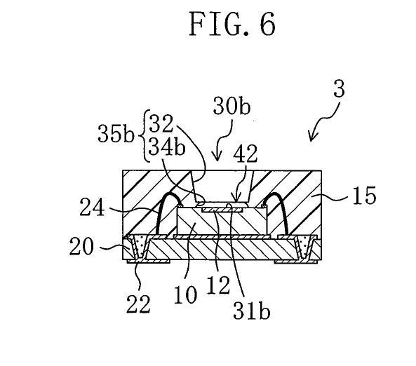

In an optical device 3 of a third embodiment shown in FIG. 6, the shape of a recess 30b is partially different from that of the recess 30 of the first embodiment. However, components such as the wiring board 20 and the wires 24 are the same as those of the first embodiment. Therefore, only the differences from the first embodiment will be described below and description of the same portions will be omitted.

In the optical device 3 of this embodiment, a second side surface 32 of a side surface 35b is the same as the second side surface 32 of the first embodiment, but a first side surface 34b of the side surface 35b is different from the first side surface 34 of the first embodiment. Unlike the first side surface 34 of the first embodiment, a bottom recess 42 formed by the first side surface 34b and the bottom surface 31b has a tapered shape having a larger opening area at the bottom. Such a bottom recess 42 can be easily formed by using a negative resist as the resist 17 placed on the optical function region 12.

A method for manufacturing the optical device 3 of this embodiment is the same as that of the first embodiment except that a negative resist is used as the resist 17.

The optical device 3 of this embodiment and the manufacturing method thereof have the same effects as those of the first embodiment.

### Fourth Embodiment

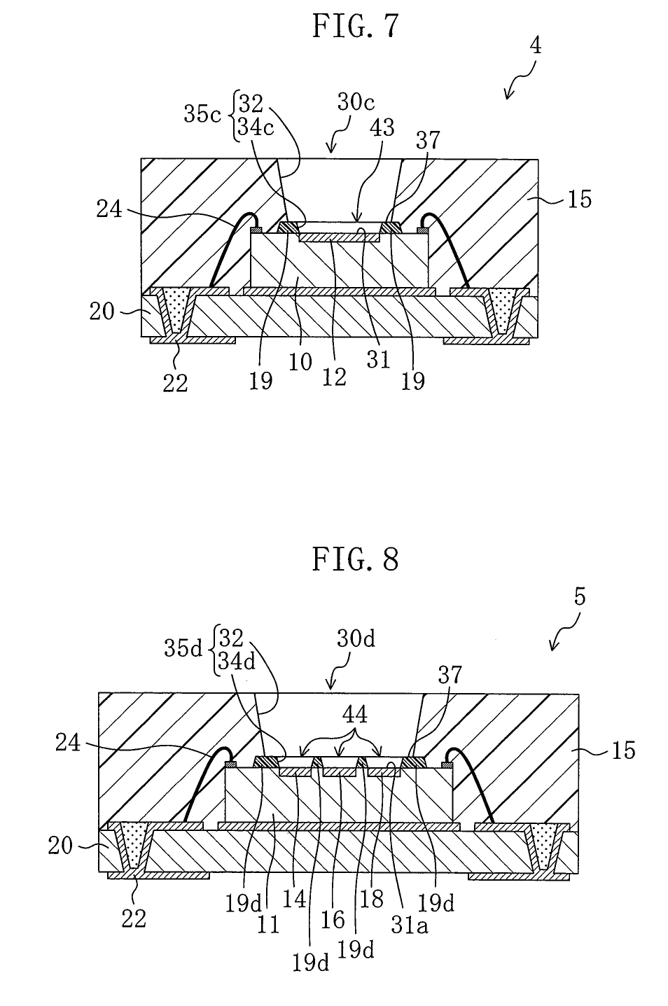

In an optical device 4 of a fourth embodiment shown in FIG. 7, the structure of a recess 30c is partially different from that of the recess 30 of the first embodiment. However, components such as the wiring board 20 and the wires 24 are the same as those of the first embodiment. Therefore, only the differences from the first embodiment will be described below and description of the same portions will be omitted.

In the optical device 4 of this embodiment, a resist 19 is formed so as to surround the optical function region 12. The resist 19 forms a first side surface 34c and a stepped portion 37. Note that a negative resist is used as the resist 19.

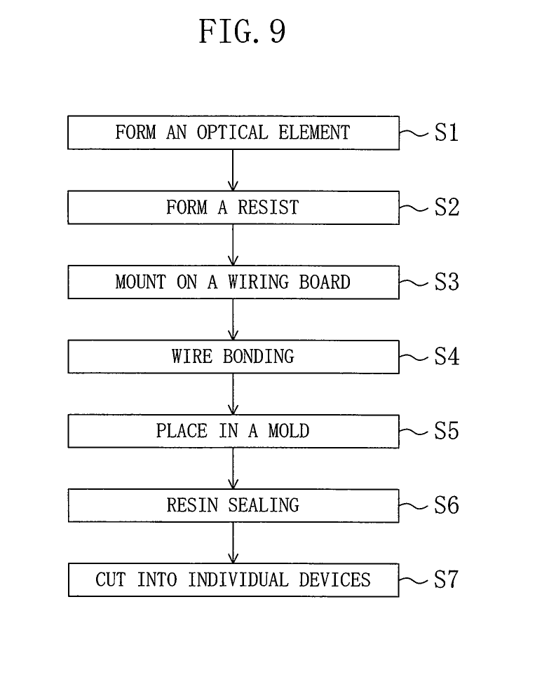

A method for manufacturing the optical device 4 of this embodiment is as shown by the flowchart of FIG. 9. The manufacturing method of this embodiment is different from that of the first embodiment in that the resist 19 is not formed on the optical function region 12 but formed around the optical function region 12 and in that the resist 19 is not removed at the end (there is no step S8). In this embodiment, the projections 55 of the mold respectively abut on the resists 19 formed around the respective optical function regions 12, and the projections 55 does not contact the respective optical function regions 12.

The optical device 4 of this embodiment and the manufacturing method thereof have the same effects as those of the first embodiment. Since the step of removing the resist 19 is not required, the manufacturing time can be reduced, whereby the cost can further be reduced.

### Fifth Embodiment

In an optical device 5 of a fifth embodiment shown in FIG. 8, the structure of a recess 30d is partially different from that of the recess 30a of the second embodiment. However, components such as the wiring board 20 and the wires 24 are the same as those of the second embodiment. Therefore, only the differences from the second embodiment will be described below and description of the same portions will be omitted.

This embodiment is implemented by applying the fourth embodiment to the second embodiment. In the optical device 5 of this embodiment, a resist 19d, 19d, . . . is provided so as to surround three optical function regions 14, 16, and 18, and the optical function regions 14, 16, and 18 are exposed as bottom surfaces 31a, 31a, and 31a of bottom recesses 44, 44, and 44, respectively. The resist 19d forms a first side surface 34d and a stepped portion 37, and the first side surface 34d and the second side surface 32 form a side surface 35d of the recess 30d.

The optical device 5 of this embodiment is manufactured by the same flow as the fourth embodiment.

The optical device 5 of this embodiment and the manufacturing method thereof have the same effects as those of the fourth embodiment.

### Other Embodiments

The above embodiments are exemplary of the invention only, and the invention is not limited to the above embodiments. For example, the protrusions of the upper mold of the mold do not necessarily have a tapered shape and may protrude with a fixed diameter. A member for preventing contact between the protrusion and the optical function region is not limited to the resist, and anything may be used as long as it serves as a cushion for the protrusions and can be easily removed in a later step.

The optical element may be made of Si (silicon) or any material such as a compound semiconductor like SiC (silicon carbide) and GaN (gallium nitride) as long as the material can provide an optical function. The optical function region may be a light-emitting region.

The wiring board may be made of any material such as resin (e.g., polyimide) and ceramic as long as the material can be used as a wiring board material.

In the manufacturing methods of the first, second, and third embodiments, the order of the step S7 of cutting the wiring board into individual devices and the step S8 of removing the resist may be reversed.

In the third embodiment, a plurality of bottom recesses may be formed as in the second embodiment. A positive resist may be used in the fourth and fifth embodiments.

As has been described above, the optical device according to the invention is useful as, for example, a small optical device having an exposed optical function region and receiving and emitting short-wavelength light.

The resist is applied to each optical function region, and resin sealing is performed with each resist being in contact with the respective projection of the mold. Therefore, the optical function region is not damaged by the mold. By removing the resist, the optical function region can be exposed without any damages. An optical device having an exposed optical function region can thus be manufactured by a simple method with high yield. Moreover, the optical function region is not damaged by the mold in a second method in which the resist is applied so as to surround each optical function region and resin sealing is performed with each resist being in contact with the respective protrusion of the mold. Since the resist does not need to be removed in the second method, an optical device having an exposed optical function region can be manufactured by a simpler method with high yield.

What is claimed is:

1. An optical device, comprising:
an optical element having an optical function region on one surface;
a wiring board having the optical element mounted thereon and electrically connected to the optical element;
a sealing resin for sealing at least an electrically connected portion of the optical element and the wiring board; and
a recess in which the optical function region serves as a bottom surface and at least a part of a side surface is formed by the sealing resin, wherein
the side surface has a first side surface extending from the bottom surface partway up a depth of the recess and a second side surface located above the first side surface,
a bottom recess is formed by the bottom surface and the first side surface,
a region surrounded by a lower end of the second side surface is larger in area than a region surrounded by an upper end of the first side surface, and
the first side surface and the second side surface are connected to each other by a stepped portion that extends from the upper end of the first side surface to the lower end of the second side surface.

2. The optical device according to claim 1, wherein the recess has a plurality of bottom recesses separated from each other by the sealing resin.

3. The optical device according to claim 1, wherein the second side surface is formed by the sealing resin, and the first side surface is formed by a resin different from the sealing resin.

4. The optical device according to claim 3, wherein the recess has a plurality of bottom recesses separated from each other by the resin different from the sealing resin.

5. The optical device according to claim 1, wherein, in a portion of the recess which is surrounded by the second side surface, the recess has a tapered shape having a larger opening area on an upper side.

6. The optical device according to claim 1, wherein the bottom recess has a tapered shape having a smaller opening area on a bottom-surface side.

7. The optical device according to claim 1, wherein the bottom recess has a tapered shape having a larger opening area on a bottom-surface side.

8. A method for manufacturing an optical device including an optical element having an optical function region on one surface, and a wiring board having the optical element mounted thereon and electrically connected to the optical element, comprising the steps of:
forming a resist on the optical function region of the optical element;
mounting another surface of the optical element on the wiring board;
electrically connecting the optical element with the wiring board;
resin-sealing at least an electrically connected portion of the optical element and the wiring board by using a mold; and
exposing the optical function region by removing the resist, wherein
the mold includes a lower mold placed on an opposite surface of an optical element mounting surface of the wiring board, and an upper mold for placing the wiring board having the optical element mounted thereon between the upper mold and the lower mold, and the upper mold has a projection that is in contact with the resist.

9. A method for manufacturing an optical device including an optical element having an optical function region on one surface, and a wiring board having the optical element mounted thereon and electrically connected to the optical element, comprising the steps of:
forming a resist on the one surface of the optical element so as to surround the optical function region;
mounting another surface of the optical element on the wiring board;
electrically connecting the optical element with the wiring board; and
resin-sealing at least an electrically connected portion of the optical element and the wiring board by using a mold, wherein
the mold includes a lower mold placed on an opposite surface of an optical element mounting surface of the wiring board, and an upper mold for placing the wiring board having the optical element mounted thereon between the upper mold and the lower mold, and the upper mold has a projection that is in contact with the resist.
